(19) United States
(12) Patent Application Publication
(10) Pub. No.: US 2012/0160549 A1
(43) Pub. Date: Jun. 28, 2012

(54) PRINTED CIRCUIT BOARD HAVING EMBEDDED ELECTRONIC COMPONENT AND METHOD OF MANUFACTURING THE SAME

(75) Inventors: Moon Il Kim, Daejeon (KR); Yul Kyo Chung, Gyunggi-do (KR); Jung Soo Byun, Gyunggi-do (KR)

(73) Assignee: SAMSUNG ELECTRO-MECHANICS CO., LTD., Gyunggi-do (KR)

(21) Appl. No.: 13/030,837

(22) Filed: Feb. 18, 2011

(30) Foreign Application Priority Data
Dec. 23, 2010 (KR) 1020100133682

(51) Int. Cl. H05K 1/09; H05K 3/00; H05K 1/16

(52) U.S. Cl. 174/257; 174/260; 29/829

(57) ABSTRACT

Disclosed is a printed circuit board having an embedded electronic component, including a metal substrate having a first cavity formed in a thickness direction and a support plate integrated with one side of the metal substrate and formed in the first cavity. Thereby, a method of manufacturing such a printed circuit board is also provided. When manufacturing the printed circuit board having an embedded electronic component, there is no need for an additional member including support tape to seat the electronic component, thus simplifying the manufacturing process and reducing lead time, thereby improving productivity.

### CROSS REFERENCE TO RELATED APPLICATION

This application claims the benefit of Korean Patent Application No. 10-2010-0133682, filed Dec. 23, 2010, entitled “A printed circuit board comprising embedded electronic component within and a method for manufacturing”, which is hereby incorporated by reference in its entirety into this application.

### BACKGROUND OF THE INVENTION

1. Technical Field

The present invention relates to a printed circuit board (PCB) having an embedded electronic component and a method of manufacturing the same.

2. Description of the Related Art

Typically circuit boards include a variety of active and passive elements such as a resistor, a capacitor, an inductor, a transformer, a filter, a mechanical switch, a relay and so on. On the other hand, electronic devices are configured such that respective elements are systematically connected so that they can efficiently perform their original functions. Thus, when power is applied to circuits, various passive or active elements of the electronic devices execute their functions.

In particular, because of the actual demand for semiconductor packages having a reduced profile and various functions, a variety of techniques are required to fabricate PCBs. Recently the development of embedded PCBs is receiving attention as a kind of next-generation multifunctional and small packaging technology. The embedded PCB is manufactured by inserting three passive elements that are fundamentally required when constituting an electronic circuit, for example, a capacitor (C), a resistor (R) and an inductor (L), which have been conventionally mounted on the surface of a substrate, into a PCB so that their functions are executed in the PCB, advantageously reducing the area of passive elements on the surface of the substrate. Furthermore, because the size of the PCB is reduced, it is expected to increase the efficiency of products and decrease the PCB price, and also, because the length of the connection between active and passive elements is shortened, the number of inductance components may be decreased, thus improving electrical performance. Moreover, because the number of solder bonds may be lowered, PCB mounting reliability may be improved.

Also the embedded PCB in which elements are mounted in a PCB in accordance with the demand of multi-functionality and miniaturization is highly functionalized to some degree. For instance, the distance of the wiring may be minimized at high frequency of 100 MHz or more, and the problems of reliability resulting from connecting components using the wire bonding or solder balls used in flip chip or BGA (Ball Grid Array) may be solved, as needed.

However, the fabrication of PCBs having electronic components embedded therein additionally requires a support tape for supporting embedding of an electronic component in a cavity that is formed in a PCB. After the embedding process, such a support tape should be removed, undesirably complicating the fabrication process. Furthermore, in order to eliminate the residue left behind after removing the support tape, surface treatment should be additionally performed. Also, when electronic components are embedded, it is not easy to precisely align the positions where the electronic components are embedded. Also in the case where a via is directly formed in the electrode of the passive element, electrical reliability may deteriorate depending on the type of material of the electrode, or accuracy of the operation may decrease due to the material deforming.

### SUMMARY OF THE INVENTION

Accordingly, the present invention has been made keeping in mind the problems encountered in the related art and the present invention is intended to provide a PCB having an embedded electronic component and a method of manufacturing the same, in which a metal substrate is used so that a cavity with a support plate is processed thus facilitating the embedding of the electronic component, and an electrical connection may be achieved using not only a via connected to the electrode of the electronic component but also a via directly connected to the metal substrate, thus enabling a variety of electronic components to be embedded.

An aspect of the present invention provides a PCB having an embedded electronic component, comprising a metal substrate having a first cavity formed in a thickness direction, a support plate integrated with one side of the metal substrate and formed in the first cavity, a passive element having an upper electrode and a lower electrode seated on the support plate, a conductive adhesive layer formed between the upper electrode or lower electrode of the passive element and the support plate, an insulating layer charged in the cavity and formed on the metal substrate, and a circuit layer formed on the insulating layer and including a via electrically connected with the electrode of the passive element.

In this aspect, the PCB may further comprise an active element having an electrode seated on the support plate of the cavity, and a circuit layer including a via so as to be electrically connected with the electrode of the active element.

In this aspect, the conductive adhesive layer may be formed of solder, a silver paste, a copper paste, or an anisotropic conductive adhesive.

In this aspect, the PCB may further comprise a solder resist layer having an opening formed on the circuit layer.

Another aspect of the present invention provides a PCB having an embedded electronic component, comprising a metal substrate having a first cavity formed in a thickness direction, a support plate integrated with one side of the metal substrate and formed in the first cavity, a second cavity formed in a portion of a center of the support plate in a thickness direction, a passive element having a first electrode seated on one support plate portion of the second cavity and a second electrode seated on the other support plate portion of the second cavity, a first conductive adhesive layer formed between the first electrode and the one support plate portion of the second cavity, a second conductive adhesive layer formed between the second electrode and the other support plate portion of the second cavity, an insulating layer charged in the cavity and formed on the metal substrate, and a circuit layer including a via formed so as to be electrically connected with the metal substrate integrated with the one support plate portion or the other support plate portion on which the first electrode or the second electrode is seated.

In this aspect, the first conductive adhesive layer or the second conductive adhesive layer may be formed of solder, a silver paste, a copper paste, an anisotropic conductive adhesive, or combinations thereof.

In this aspect, the PCB may further comprise a solder resist layer having an opening formed on the circuit layer.

A further aspect of the present invention provides a method of manufacturing a PCB having an embedded electronic component, comprising preparing a metal substrate, forming a first cavity so as to provide a support plate integrated with one side of the metal substrate, seating a passive element having an upper electrode and a lower electrode so as to be adhered to the support plate of the first cavity by means of a conductive adhesive layer, forming an insulating layer on the metal substrate while filling the first cavity therewith, and forming a circuit layer including a via electrically connected with the electrode of the passive element on the insulating layer.

In this aspect, the conductive adhesive layer may be formed of solder, a silver paste, a copper paste, an anisotropic conductive adhesive, or combinations thereof.

In this aspect, the method may further comprise forming a solder resist layer having an opening on the circuit layer.

Still a further aspect of the present invention provides a method of manufacturing a PCB having an embedded electronic component, comprising preparing a metal substrate, forming a first cavity so as to provide a support plate integrated with one side of the metal substrate, forming a second cavity in a portion of a center of the support plate in a thickness direction, seating a passive element having a first electrode adhered to one support plate portion of the second cavity by means of a first conductive adhesive layer and a second electrode adhered to the other support plate portion of the second cavity by means of a second conductive adhesive layer, forming an insulating layer on the metal substrate while filling the second cavity therewith, and forming a circuit layer including a via formed in the insulating layer, wherein the via is formed to be electrically connected to the metal substrate including the one support plate portion and the other support plate portion.

In this aspect, the conductive adhesive layer may be formed of solder, a silver paste, a copper paste, an anisotropic conductive adhesive, or combinations thereof.

In this aspect, the method may further comprise forming a solder resist layer having an opening on the circuit layer.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a PCB having an embedded electronic component according to a first embodiment of the present invention;

FIG. 2 is a cross-sectional view showing a PCB having an embedded electronic component according to a second embodiment of the present invention;

FIGS. 3 to 8 are cross-sectional views sequentially showing a process of manufacturing the PCB having an embedded electronic component according to the first embodiment of the present invention; and

FIGS. 9 to 15 are cross-sectional views sequentially showing a process of manufacturing the PCB having an embedded electronic component according to the second embodiment of the present invention.

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. In the description, the terms “one side”, “the other side”, “first”, “second” and so on are used to distinguish one element from another element and not to define the elements. Moreover, descriptions of known techniques, even if they are pertinent to the present invention, are regarded as unnecessary and may be omitted when they would make the characteristics of the invention and the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

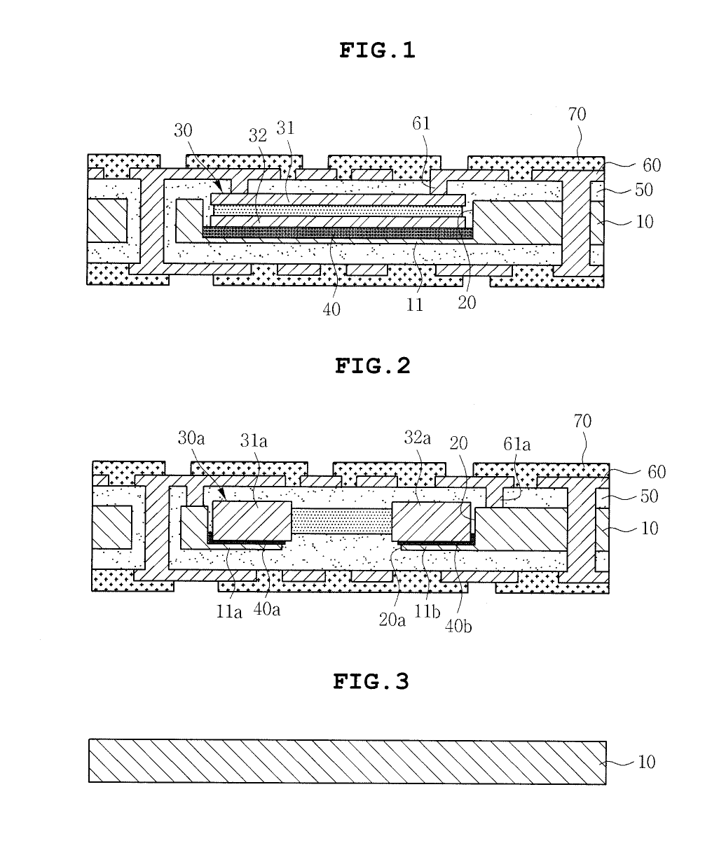

FIG. 1 is a cross-sectional view showing a PCB having an embedded electronic component according to a first embodiment of the present invention, and FIG. 2 is a cross-sectional view showing a PCB having an embedded electronic component according to a second embodiment of the present invention.

The PCB having an embedded electronic component according to the first embodiment of the present invention includes a metal substrate 10 having a first cavity 20 formed in a thickness direction, a support plate 11 integrated with one side of the metal substrate 10 and formed in the first cavity 20, a passive element 30 having an upper electrode 31 and a lower electrode 32 seated on the support plate 11, a conductive adhesive layer 40 formed between the upper electrode 31 or lower electrode 32 of the to passive element 30 and the support plate 11, an insulating layer 50 charged in the first cavity 20 and formed on the metal substrate 10, and a circuit layer 60 formed on the insulating layer 50 and including a via 61 that is electrically connected with the upper electrode 31 or lower electrode 32 of the passive element 30.

The metal substrate 10 may be formed of a metal material such as copper, aluminum, magnesium or titanium, and the material thereof is not particularly limited so long as it is electrically conductive and has heat-radiating properties. A substrate made of any metal material may be used. The metal substrate 10 has the first cavity 20 formed in a thickness direction in order to embed the electronic component. The first cavity 20 may be formed using mechanical processing or any other method. In the present invention, etching may be performed to form the cavity in the metal substrate 10.

The support plate 11 is integrated with one side of the metal substrate 10 and is formed in the first cavity 20. Although the integrated support plate may be separately formed, one side of the metal substrate 10 is left behind at an appropriate thickness upon etching of the metal substrate 10, and thereby the support plate 11 may be formed. Upon etching of the first cavity 20 of the metal substrate 10, a portion of the metal substrate 10 in which the first cavity 20 is formed is left behind to form the support plate 11. Thereby, a first cavity 20 that is adapted to the thickness of the mounted electronic component may be formed, and hence, any electronic component 30 may be mounted regardless of the thickness of the metal substrate 10. The support plate 11 may be formed in such a manner that a portion of the metal substrate 10 is provided in the form of a support plate 11 by adjusting the degree of etching upon formation of the first cavity 20 of the metal substrate 10, but the present invention is not limited thereto. The support plate may be manufactured by integrally bonding an additional member to the metal substrate 10. After the electronic component is seated, the support plate 11 according to the present invention is not removed but is left behind as part of the PCB so as to create an electrical connection of the electronic component, which is different from a conventional process which includes using an additional support tape to embed an electronic component and then removing the support tape.

In the present invention, the electronic component includes the passive element 30 and an active element (not shown). Below, the case where the passive element 30 is mounted according to the first embodiment is described. The passive element 30 includes the upper electrode 31 and the lower electrode 32. The upper electrode 31 or lower electrode 32 of the passive element 30 may be seated on the support plate 11. In order to securely bond the passive element 30 onto the support plate 11, a conductive adhesive layer 40 may be provided.

The conductive adhesive layer 40 is used to adhere the upper electrode 31 or lower electrode 32 of the passive element 30 to the support plate 11, and may be formed using solder, a silver paste, a copper paste, an anisotropic conductive adhesive, or combinations thereof. The material and kind of the conductive adhesive layer 40 are not limited thereto, and any material and kind thereof may be used to form the conductive adhesive layer 40 so long as it is conductive and adhesive.

The insulating layer 50 is formed on the metal substrate 10 when it fills the first cavity 20 including the support plate 11. The insulating layer is simultaneously on one side and the other side of the metal substrate 10, and the electronic component may be embedded by introducing an insulating material into the hollow support plate 11 and then curing the insulating layer 50. As such, the present invention is not necessarily limited to complete curing. In the course of embedding the electronic component, the material of the insulating layer 50 may include an insulating material having high fluidity, but is not particularly limited thereto. For example, various insulating materials such as a prepreg may be used.

The circuit layer 60 is formed on the insulating layer 50 and may include the via 61 for an electrical connection of the passive element 30. Also in the case where an active element is mounted, a via connected with the electrode of the active element may to be formed. The circuit layer 60 may be formed to further include a via 61 in order to electrically connect the upper electrode 31 or lower electrode 32 of the passive element 30. The via 61 may be formed by processing the insulating layer 50 using a mechanical drill such as a CNC (Computer Numerical Control) drill, and the processing is not necessarily limited thereto. As shown in FIG. 1, in the case where the passive element 30 is mounted in the PCB, the via 61 may also be formed in the insulating layer 50 in order to make it possible to form an electrical connection with the upper electrode 31 or lower electrode 32 of the passive element 30.

The circuit layer 60 may be formed using a subtractive process or an additive process. In addition, various methods may be applied to form the circuit layer 60. For example, although not shown in the drawings, the semi-additive formation of the circuit layer 60 includes forming a seed layer on the insulating layer 50, applying a plating resist to form the circuit layer 60, forming a circuit plating layer on the plating resist, removing the plating resist, and removing the exposed seed layer using selective etching. As such, the seed layer functions as a lead wire for electroplating, and may be formed using wet plating (electroless plating) or dry plating (sputtering) in order to subsequently form the circuit plating layer. After formation of the circuit layer 60, a solder resist layer 70 may be formed on a portion of the circuit layer 60 other than a terminal thereof in order to protect the circuit layer 60.

According to the second embodiment of the present invention, the PCB having an embedded electronic component includes a metal substrate having a first cavity formed in a thickness direction, a support plate integrated with one side of the metal substrate and formed in the first cavity, a second cavity formed in a portion of the center of the support plate in a thickness direction, a passive element having a first electrode seated on one support plate portion of the second cavity and a second electrode seated on the other support plate portion of the second cavity, a first conductive adhesive layer formed between the first electrode and one support plate portion of the second cavity, a second conductive adhesive layer formed between the second electrode and the other support plate portion of the second cavity, an insulating layer charged in the cavities and formed on the metal substrate, and a circuit layer having a via formed so as to be electrically connected with the metal substrate integrated with one support plate portion or the other support plate portion on which the first electrode or the second electrode is seated.

Below the description which overlaps that of the PCB having an embedded electronic component according to the first embodiment of the present invention is omitted.

In the PCB having an embedded electronic component according to the second embodiment of the present invention, the second cavity 20a is formed in a portion of the center of the support plate, so that the first electrode 31a and the second electrode 32a of the passive element 30a are seated on one support plate portion 11a and the other support plate portion 11b of the second cavity 20a, respectively, thus mounting the passive element 30a. In order to prevent the first electrode 31a and the second electrode 32a from shorting out, the cavity is formed in the center of the support plate 11 thus preventing an electrical connection from being made. In the second embodiment of the present invention, the first electrode 31a and the second electrode 32a of the mounted passive element 30a are disposed parallel to a longitudinal direction of the metal substrate 10, unlike the plate type passive element 30 according to the first embodiment. The first electrode 31a and the second electrode 32a of the passive element 30a according to the present invention are formed of tin and thus have poor heat resistance. So in the course of forming the via in the first electrode 31a and the second electrode 32a, the electrodes may be undesirably damaged or deformed. When the electrodes are respectively disposed on the one support plate portion 11a and the other support plate portion 11b of the metal substrate 10 and are electrically connected to the metal substrate 10 by means of the via 61a, the electrical connection of the passive element 30a may be achieved even without forming the via which is directly connected to the first electrode 31a and the second electrode 32a. Specifically, when providing the circuit layer 60 including the via 61a formed so as to be electrically connected to the metal substrate 10 integrated with one support plate portion 11a or the other support plate portion 11b on which the first electrode 31a or the second electrode 32a is seated, problems of the electrodes being damaged or shorting out depending on the material of the first electrode 31a or the second electrode 32a may be solved, and the electrical connection of the electronic component may be accomplished. In the case of a passive element 30a different from the passive element 30 used in the first embodiment, the mounting structure according to the second embodiment is provided, thereby improving electrical reliability and the operation of PCBs.

In order to adhere the first electrode 31a or the second electrode 32a to the one support plate portion 11a or the other support plate portion 11b, the first conductive adhesive layer 40a or the second conductive adhesive layer 40b may be formed. The first conductive adhesive layer 40a and the second conductive adhesive layer 40b are the same as the conductive adhesive layer 40 according to the first embodiment, and thus the description thereof is omitted herein.

FIGS. 3 to 8 sequentially show the process of manufacturing the PCB having an embedded electronic component according to the first embodiment of the present invention. The method of manufacturing the PCB having an embedded electronic component according to the first embodiment of the present invention includes preparing a metal substrate 10, forming a first cavity 20 so as to provide a support plate 11 integrated with one side of the metal substrate 10, seating a passive element 30 to adhere it to the support plate 11 of the first cavity 20 using a conductive adhesive layer 40, forming an insulating layer 50 on the metal substrate 10 while filling the first cavity 20 therewith, and forming a circuit layer 60 including a via 61 on the insulating layer 50, the via being electrically connected with the upper electrode 31 or lower electrode 32 of the passive element 30.

Below, the description which overlaps that of the PCB having an embedded electronic component according to the first and second embodiments is omitted.

FIG. 3 shows preparing the metal substrate 10. The metal substrate 10 is not particularly limited so long as it is conductive and may be used for a PCB. For example, the use of a metal substrate 10 made of copper, aluminum, titanium or combinations thereof is possible.

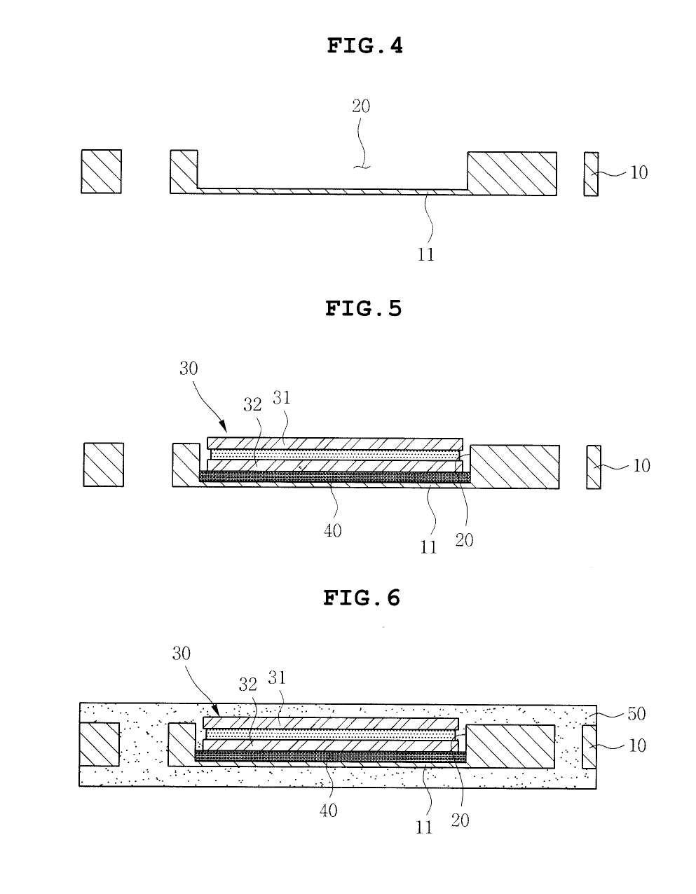

FIG. 4 shows forming the first cavity 20 in the metal substrate 10. The first cavity 20 is formed to include the support plate 11 connected to one side of the metal substrate 10 and integrated with the metal substrate 10. Thus, the first cavity 20 formed in a thickness direction of the metal substrate 10 is not a cavity top and bottom of which are completely opened but is a cavity one side of which is closed by the support plate 11. When the support plate 11 is formed, the mounting of the electronic component is possible, and the need to form an additional member such as a conventional support tape is no longer present, and the cavity may be formed so as to be adapted to the thickness of the mounted electronic component regardless of the thickness of the metal substrate 10. The first cavity 20 may be formed using a mechanical process, but etching may be applied in the present invention.

FIG. 5 shows mounting the electronic component on the metal substrate 10 having the first cavity 20. As shown in FIG. 5, the mounted electronic component may be a passive element 30 but the present invention is not necessarily limited thereto. Any type of electronic component including an active element may be mounted. In FIG. 5, the case where the passive element 30 having an upper electrode 31 and a lower electrode 32 is mounted is illustrated. As in FIG. 5, the passive element 30 is provided such that the upper electrode 31 or lower electrode 32 thereof is seated on the support plate 11, and the conductive adhesive layer 40 is formed to adhere the electrode and the support plate 11 to each other. Because the electrical connection is achieved by means of the metal substrate 10, an adhesive layer which is conductive may be used. The conductive adhesive layer 40 may be formed of solder, a silver paste, a copper paste, an anisotropic conductive adhesive or combinations thereof. Any kind and material may be applied to form the conductive adhesive layer 40 so long as it is conductive and adhesive.

FIG. 6 shows forming the insulating layer 50 on the metal substrate 10 while filling the first cavity 20 therewith. In order to fill the first cavity 20 and embed the electronic component, the insulating layer 50 may be made of a semi-cured prepreg which has high fluidity, but the present invention is not necessarily limited thereto. Any insulating material may be used to form the insulating layer 50 so long as it has insulating properties and good fluidity. The insulating layer 50 may be simultaneously formed on both sides of the metal substrate 10, thereby simplifying the manufacturing process and preventing the PCB from warping thanks to double-sided layering.

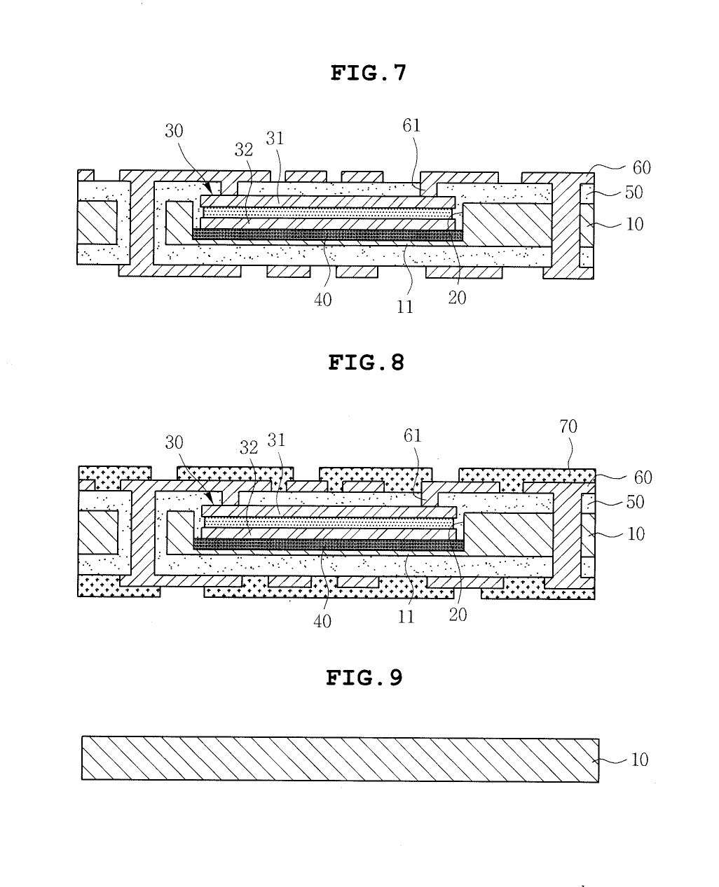

FIG. 7 shows forming the circuit layer 60 on the insulating layer 50. The circuit layer 60 may be formed to include the via 61. In the present embodiment, the circuit layer 60 including the via 61 may be formed so as to be connected with the upper electrode 31 or lower electrode 32 of the passive element 30. The formation of the circuit layer 60 including the via 61 to form an electrical connection with the upper electrode 31 of the passive element 30 is illustrated in FIG. 7. In this case, the via 61 is directly connected to the electrode, thereby further improving the reliability of the electrical connection.

FIG. 8 shows forming the solder resist layer 70 on the circuit layer 60. After formation of the circuit layer 60, the solder resist layer is formed to protect a portion of the circuit layer 60 other than the terminal thereof and prevent undesired solder bridges. The solder resist layer 70 may be formed by applying a solder resist using a typical process, for example, screen printing or roller coating, performing photo-exposure and development and then finally performing curing.

FIGS. 9 to 15 sequentially show the process of manufacturing the PCB having an embedded electronic component according to the second embodiment of the present invention. The method of manufacturing the PCB having an embedded electronic component according to the second embodiment of the present invention includes preparing a metal substrate 10, forming a first cavity 20 so as to provide a support plate 11 integrated with one side of the metal substrate 10, forming a second cavity 20a in a portion of the center of the support plate 11 in a thickness direction, seating a passive element 30a having a first electrode 31a adhered to one support plate portion 11a of the second cavity 20a by means of a first conductive adhesive layer 40a and a second electrode 32a adhered to the other support plate portion 11b of the second cavity 20a by means of a second conductive adhesive layer 40b, forming an insulating layer 50 on the metal substrate 10 while filling the second cavity 20a therewith, and forming a circuit layer 60 including a via 61a formed in the insulating layer, in which the via 61a is electrically connected to the metal substrate 10 including one support plate portion 11a and the other support plate portion 11b.

Below, the description which overlaps the descriptions of the PCB having an embedded electronic component according to the first and second embodiments and of the method of manufacturing the PCB having an embedded electronic component according to the first embodiment is omitted.

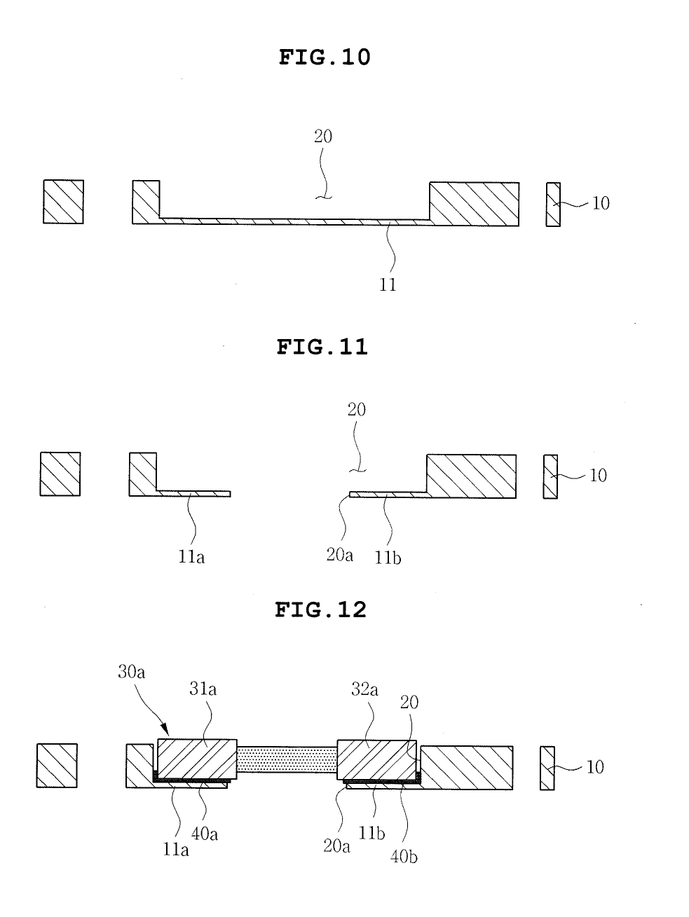

FIG. 9 shows preparing the metal substrate 10, and FIG. 10 shows forming the first cavity 20 in the metal substrate 10. The first cavity 20 is formed to include the support plate 11 that is connected to one side of the metal substrate 10 and is integrated with the metal substrate 10. The support plate 11 may be formed at the same time that the first cavity 20 is formed, or may be formed separately integrated after formation of the first cavity 20.

FIG. 11 shows forming the second cavity 20a in a portion of the center of the support plate 11 in a thickness direction. When the second cavity 20a is formed in the portion of the center of the support plate 11, the support plate includes one support plate portion 11a and the other support plate portion 11b by the second cavity 20a therebetween. The second cavity 20a is formed such that the passive element 30a in which the first electrode 31a and the second electrode 32a are formed at both ends in a horizontal direction is embedded, unlike the plate type passive element 30 in the method of manufacturing the PCB having an embedded electronic component according to the first embodiment. Because the first electrode 31a and the second electrode 32a should be electrically insulated from each other in order to prevent them from shorting out, the passive element 30a is mounted by forming the second cavity 20a.

FIG. 12 shows seating the passive element 30a including the first electrode 31a adhered to one support plate portion 11a of the second cavity 20a by means of the first conductive adhesive layer 40a, and the second electrode 32a adhered to the other support plate portion 11b of the second cavity 20a by means of the second conductive adhesive layer 40b. As above, because the first electrode 31a and the second electrode 32a of the passive element 30a are mounted parallel to each other on the PCB, the first electrode 31a and the second electrode 32a may be respectively seated on the one support plate portion 11a and the other support plate portion 11b. The first electrode 31a and the second electrode 32a are adhered to the one support plate portion 11a and the other support plate portion 11b, respectively, and the first conductive adhesive layer 40a and the second conductive adhesive layer 40b may be formed to enable the electrical connection to be made. The description of the first conductive adhesive layer 40a and the second conductive adhesive layer 40b is the same as that of the conductive adhesive layer 40 as above and is thus omitted herein.

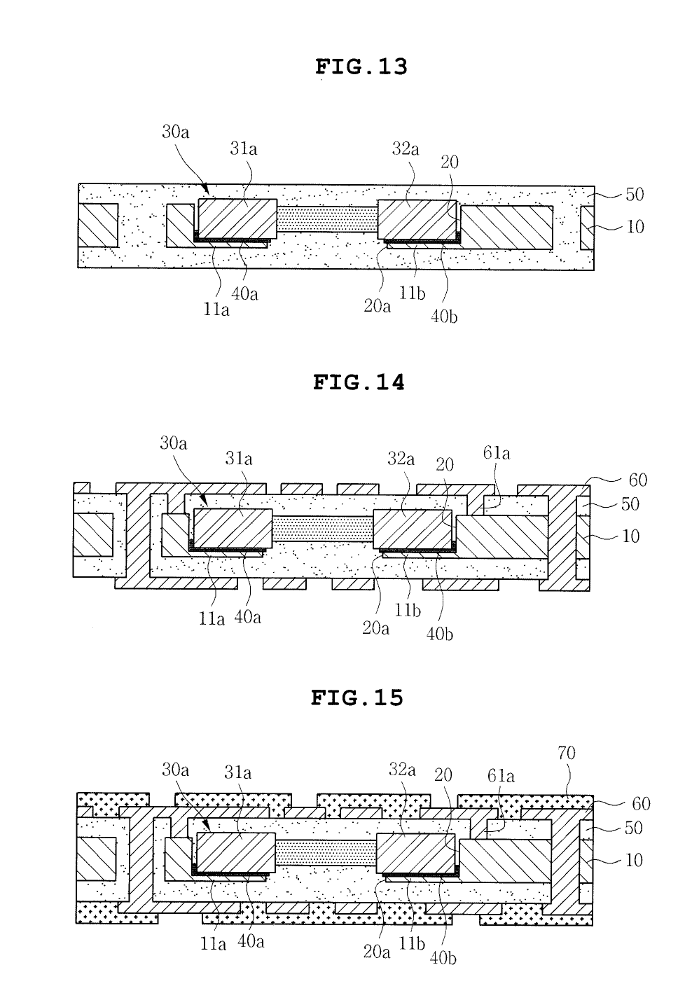

FIG. 13 shows forming the insulating layer 50 on both sides of the metal substrate 10 while filling the first cavity 20 and the second cavity 20a therewith. In order to embed the electronic component by filing the first cavity 20 and the second cavity 20a, the insulating layer 50 may be formed of a semi-cured prepreg having high fluidity, and any material may be used without limitation to form the insulating layer 50 so long as it has insulating properties and high fluidity.

FIG. 14 shows forming the circuit layer 60 on the insulating layer 50. The circuit layer 60 may be formed to include the via 61a. In the present embodiment, the first electrode 31a and the second electrode 32a of the passive element 30a are formed of tin. In the case where the via for an electrical connection is directly connected with the first electrode 31a and the second electrode 32a, the electrodes of the passive element 30a may be damaged or deformed by heat or impact due to processing of the via. Hence, the via 61a for an electrical connection is formed in portions of the metal substrate 10 connected with the one support plate portion 11a and the other support plate portion 11b on which the first electrode 31a and the second electrode 32a are seated, thereby improving reliability of the electrical connection of the passive element 30a.

FIG. 15 shows forming the solder resist layer 70 on the circuit layer 60. The solder resist layer is formed to protect the portion of the formed circuit layer 60 other than the terminal thereof and to prevent undesired solder bridges.

As described hereinbefore, the present invention provides a PCB having an embedded electronic component and a method of manufacturing the same. According to the present invention, the fabrication of the PCB having an embedded electronic component obviates a need for an additional member such as a support tape for seating the electronic component, thus simplifying the manufacturing process and reducing the lead time, resulting in increased productivity.

Also, in the case of using a support tape to seat the electronic component, it may leave behind a residue after it is removed. However, because such an additional member is not used in the present invention, there is no residue, thus increasing electrical reliability of the electronic component and accuracy of the operation of the PCB having an embedded electronic component.

Also, in the case where the electronic component is embedded, the alignment for seating the electronic component at an accurate position can be enhanced.

Also, even when electrodes of the passive element have poor heat resistance, a circuit layer including a via is formed on the metal substrate connected with a portion on which the electrode of the passive element is seated, thus increasing the reliability of the electrical connection with the passive element and preventing the electrodes of the passive element from being deformed and damaged.

Although the embodiments of the present invention regarding the PCB having an embedded electronic component therein and the method of manufacturing the same have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A printed circuit board having an embedded electronic component, comprising:
a metal substrate having a first cavity formed in a thickness direction;
a support plate integrated with one side of the metal substrate and formed in the first cavity;
a passive element having an upper electrode and a lower electrode seated on the support plate;
a conductive adhesive layer formed between the upper electrode or lower electrode of the passive element and the support plate;
an insulating layer charged in the cavity and formed on the metal substrate; and
a circuit layer formed on the insulating layer and including a via electrically connected with the electrode of the passive element.

2. The printed circuit board of claim 1, further comprising an active element having an electrode seated on the support plate of the cavity; and a circuit layer including a via so as to be electrically connected with the electrode of the active element.

3. The printed circuit board of claim 1, wherein the conductive adhesive layer is formed of solder, a silver paste, a copper paste, or an anisotropic conductive adhesive.

4. The printed circuit board of claim 1, further comprising a solder resist layer having an opening formed on the circuit layer.

5. A printed circuit board having an embedded electronic component, comprising:
a metal substrate having a first cavity formed in a thickness direction;
a support plate integrated with one side of the metal substrate and formed in the first cavity;
a second cavity formed in a portion of a center of the support plate in a thickness direction;
a passive element having a first electrode seated on one support plate portion of the second cavity and a second electrode seated on the other support plate portion of the second cavity;
a first conductive adhesive layer formed between the first electrode and the one support plate portion of the second cavity;
a second conductive adhesive layer formed between the second electrode and the other support plate portion of the second cavity;
an insulating layer charged in the cavity and formed on the metal substrate; and
a circuit layer including a via formed so as to be electrically connected with the metal substrate integrated with the one support plate portion or the other support plate portion on which the first electrode or the second electrode is seated.

6. The printed circuit board of claim 5, wherein the first conductive adhesive layer or the second conductive adhesive layer is formed of solder, a silver paste, a copper paste, an anisotropic conductive adhesive, or combinations thereof.

7. The printed circuit board of claim 5, further comprising a solder resist layer having an opening formed on the circuit layer.

8. A method of manufacturing a printed circuit board having an embedded electronic component, comprising:
preparing a metal substrate;
forming a first cavity so as to provide a support plate integrated with one side of the metal substrate;
seating a passive element having an upper electrode and a lower electrode so as to be adhered to the support plate of the first cavity by means of a conductive adhesive layer;
forming an insulating layer on the metal substrate while filling the first cavity therewith; and
forming a circuit layer including a via electrically connected with the electrode of the passive element on the insulating layer.

9. The method of claim 8, wherein the conductive adhesive layer is formed of solder, a silver paste, a copper paste, an anisotropic conductive adhesive, or combinations thereof.

10. The method of claim 8, further comprising forming a solder resist layer having an opening on the circuit layer.

11. A method of manufacturing a printed circuit board having an embedded electronic component, comprising:
preparing a metal substrate;
forming a first cavity so as to provide a support plate integrated with one side of the metal substrate;
forming a second cavity in a portion of a center of the support plate in a thickness direction;
seating a passive element having a first electrode adhered to one support plate portion of the second cavity by means of a first conductive adhesive layer and a second electrode adhered to the other support plate portion of the second cavity by means of a second conductive adhesive layer;
forming an insulating layer on the metal substrate while filling the second cavity therewith; and
forming a circuit layer including a via formed in the insulating layer, wherein the via is formed to be electrically connected to the metal substrate including the one support plate portion and the other support plate portion.

12. The method of claim 11, wherein the conductive adhesive layer is formed of solder, a silver paste, a copper paste, an anisotropic conductive adhesive, or combinations thereof.

13. The method of claim 11, further comprising forming a solder resist layer having an opening on the circuit layer.
